(19) United States
(12) Patent Application Publication
(10) Pub. No.: US 2026/0221980 A1
(43) Pub. Date: Jul. 30, 2026

(54) FREQUENCY ADJUSTMENT DEVICE AND FREQUENCY ADJUSTMENT METHOD

(71) Applicant: Nuvoton Technology Corporation, Hsinchu Science Park (TW)

(72) Inventor: Ching-Hsuan LI, Zhubei City (TW)

(21) Appl. No.: 19/349,290

(22) Filed: Oct. 3, 2025

(30) Foreign Application Priority Data
Jan. 24, 2025 (TW) 114103263

(51) Int. Cl. H03L 7/24

(52) U.S. Cl. CPC H03L 7/24

(57) ABSTRACT

A frequency adjustment device includes a microprocessor, a buffer, and a frequency adjustment circuit. The microprocessor is configured to receive a memory access signal. The buffer is disposed inside the microprocessor. The buffer is configured to output an input pointer signal and an output pointer signal according to the memory access signal, the input pointer signal, and the output pointer signal. The frequency adjustment circuit is disposed inside the microprocessor. The frequency adjustment circuit is configured to output a first current threshold according to the input pointer signal and the output pointer signal. The frequency adjustment circuit is further configured to output a threshold trimming signal to a time register according to a setting threshold signal and the first current threshold.

### CROSS REFERENCE TO RELATED APPLICATIONS

This Application claims priority of TW Patent Application No. 114103263, filed on Jan. 24, 2025, the entirety of which is incorporated by reference herein.

### BACKGROUND OF THE INVENTION

### Field of the Invention

The present invention relates to an adjustment device and adjustment method, and, in particular, it is related to a frequency adjustment device and frequency adjustment method.

### Description of the Related Art

Currently, with the widespread use of microcontroller units (MCUs) in various applications, effective management and utilization of system resources have become increasingly important.

When an MCU exchanges data with external devices or other system modules, mismatches in clock frequency often lead to unstable consumption rates of data buffers, thereby affecting overall system performance and reliability. In addition, frequent manual frequency adjustments not only increase the complexity of program development but also occupy valuable MCU resources, thereby impacting the execution of other critical tasks.

### BRIEF SUMMARY OF THE INVENTION

The summary of the invention is intended to provide a simplified overview of the present disclosure so that readers may have a basic understanding of the disclosure. This summary is not an exhaustive overview of the disclosure, nor is it intended to identify essential or key elements of the embodiments of the invention, or to define the scope of the invention.

An embodiment of the present invention provides a frequency adjustment device The frequency adjustment device includes a microprocessor, a buffer, and a frequency adjustment circuit. The microprocessor is configured to receive a memory access signal. The buffer is disposed inside the microprocessor. The buffer is configured to output an input pointer signal and an output pointer signal according to the memory access signal, the input pointer signal, and the output pointer signal. The frequency adjustment circuit is disposed inside the microprocessor. The frequency adjustment circuit is configured to output a first current threshold according to the input pointer signal and the output pointer signal. The frequency adjustment circuit is further configured to output a threshold trimming signal to a time register according to a setting threshold signal and the first current threshold.

In one embodiment, the frequency adjustment circuit determines whether to output an interval trimming signal according to a setting threshold of the setting threshold signal and the first current threshold; wherein when the frequency adjustment circuit determines that the setting threshold is not equal to the first current threshold, the frequency adjustment circuit outputs the interval trimming signal to the time register according to a setting interval signal.

In one embodiment, the memory access signal includes an input peripheral direct memory access signal; wherein the input pointer signal and the output pointer signal are respectively associated with the memory access signal.

In one embodiment, the frequency adjustment circuit sets a first difference value between the input pointer signal and the output pointer signal as the first current threshold; wherein the frequency adjustment circuit sets a second difference value between the setting threshold and the first current threshold as a threshold trimming value of the threshold trimming signal; wherein the frequency adjustment circuit determines whether the setting threshold is equal to the first current threshold; wherein the frequency adjustment circuit adjusts a system frequency and obtains a second current threshold according to the threshold trimming value; wherein when the frequency adjustment circuit determines that the setting threshold is equal to the second current threshold, the frequency adjustment circuit adjusts the threshold trimming value.

In one embodiment, the frequency adjustment circuit determines whether the setting threshold is equal to the first current threshold; wherein when the frequency adjustment circuit determines that the setting threshold is not equal to the first current threshold, the frequency adjustment circuit adjusts a first interval trimming value of the interval trimming signal to a second interval trimming value; wherein the frequency adjustment circuit adjusts the system frequency and obtains the second current threshold according to the second interval trimming value; wherein when the frequency adjustment circuit determines that the setting threshold is equal to the second current threshold, the frequency adjustment circuit adjusts the interval trimming signal.

Other embodiment of the present invention provides a frequency adjustment method. The frequency adjustment method includes the following steps: receiving a memory access signal; outputting the input pointer signal and the output pointer signal according to the memory access signal, the input pointer signal, and the output pointer signal; outputting a first current threshold according to the input pointer signal and the output pointer signal; and outputting a threshold trimming signal according to a setting threshold signal and the first current threshold.

In one embodiment, the frequency adjustment method further includes the following steps: determining whether to output an interval trimming signal according to a setting threshold of the setting threshold signal and the first current threshold; and when it is determined that the setting threshold and the first current threshold are not equal, outputting the interval trimming signal according to a setting interval signal.

In one embodiment, the memory access signal includes an input peripheral direct memory access signal; wherein the input pointer signal and the output pointer signal are respectively associated with the memory access signal.

In one embodiment, the frequency adjustment method further includes the following steps: during a first period, setting a first difference value between the input pointer signal and the output pointer signal as the first current threshold. during the first period, setting a second difference value between the setting threshold and the first current threshold as a threshold trimming value of the threshold trimming signal; during a second period, comparing whether the setting threshold is equal to the first current threshold; during a third period, adjusting a system frequency according to the threshold trimming value and obtaining a second current threshold; and during a fourth period, when it is determined that the setting threshold is equal to the second current threshold, restoring the threshold trimming value to zero.

In one embodiment, the frequency adjustment method further includes the following steps: during the first period, determining whether the setting threshold is equal to the first current threshold; during the second period, when it is determined that the setting threshold is not equal to the first current threshold, increasing or decreasing a first interval trimming value of the interval trimming signal by one to obtain a second interval trimming value; during the third period, adjusting the system frequency according to the second interval trimming value and obtaining a second current threshold; and during the fourth period, when it is determined that the setting threshold is equal to the second current threshold, restoring a third interval trimming value of the interval trimming signal to zero.

Therefore, according to the technical content of the present disclosure, the frequency adjustment device and frequency adjustment shown in the embodiment of the present disclosure can achieve the effect of intelligently adjusting the clock frequency by monitoring the difference between the current threshold and the setting threshold.

Upon reviewing the embodiments described below, a person of ordinary skill in the art will readily understand the basic spirit of the present invention, other objectives of the invention, as well as the technical means and embodiments adopted in the present invention.

Other features and aspects of the present disclosure will become apparent from the following detailed description of exemplary embodiments with reference to the accompanying drawings.

### BRIEF DESCRIPTION OF THE DRAWINGS

The views of the embodiments of the present disclosure can be better understood through the following detailed description combined with the accompanying drawings. It is worth noting that, according to standard industrial practice, some features may not be drawn to scale. In fact, to facilitate clear description, the dimensions of different features may be increased or decreased, wherein:

FIG. 1 is a block diagram of a frequency adjustment device according to one embodiment of the present disclosure.

FIG. 2 is a block diagram of a frequency adjustment device according to one embodiment of the present disclosure.

FIG. 3 is a block diagram of a frequency adjustment device according to one embodiment of the present disclosure.

FIG. 4 is a timing diagram of a plurality of signals of a frequency adjustment device according to one embodiment of the present disclosure.

FIG. 5 is a flowchart of a plurality of signals of a frequency adjustment method according to one embodiment of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

In order to make the description of the present disclosure more detailed and complete, illustrative descriptions of embodiments and specific examples of the present invention are provided below; however, these are not the only forms for implementing or practicing the specific embodiments of the invention. The embodiments encompass features of multiple specific examples, as well as the method steps and their sequence for constructing and operating such specific examples. Nevertheless, other specific embodiments may also be employed to achieve the same or equivalent functions and sequences of steps.

Unless otherwise defined herein, the scientific and technical terms used in this specification have the same meanings as commonly understood by a person of ordinary skill in the art to which the present invention pertains. Furthermore, unless the context clearly indicates otherwise, the singular forms used herein are intended to include the plural, and the plural forms are intended to include the singular.

In addition, the terms “coupled” or “connected” as used herein may refer to direct physical or electrical contact between two or more components, indirect physical or electrical contact between two or more components, or cooperation or interaction between two or more components.

As used herein, the term “circuit” broadly refers to an object formed by one or more transistors and/or one or more passive or active components connected in a certain manner to process signals.

Certain terms are used in the specification and the claims to refer to specific elements. However, it will be understood by a person of ordinary skill in the art that the same element may be referred to by different names. Distinctions between elements in the specification and claims are not to be made based on differences in names, but rather on functional differences. The term “comprising” as used in the specification and the claims is intended to be an open-ended term, and should be interpreted as “including but not limited to.”

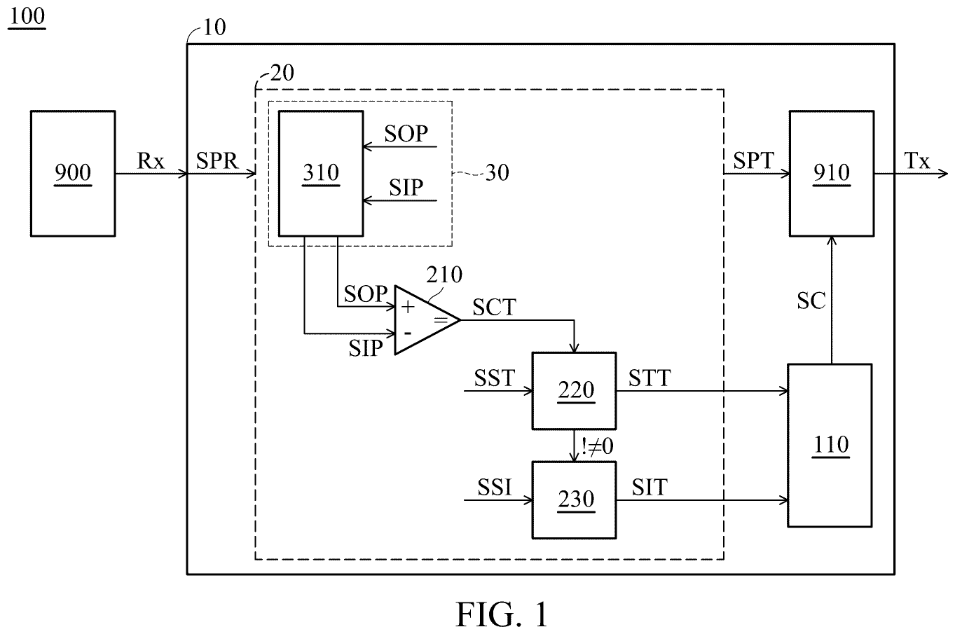

FIG. 1 is a block diagram of a frequency adjustment device according to one embodiment of the present disclosure. As shown in FIG. 1, in one embodiment, frequency adjustment device 100 includes a first interface 900, a microprocessor 10, a frequency adjustment circuit 20, a signal receiving block 30, a buffer 310, a first selector 210, a second selector 220, a third selector 230, a time register 110, and a second interface 910. The frequency adjustment circuit 20, signal receiving block 30, buffer 310, first selector 210, second selector 220, third selector 230, time register 110, and second interface 910 may be located within the microprocessor 10.

In some embodiments, the first interface 900 outputs a receiving signal Rx, and the microprocessor 10 converts the receiving signal into a memory access signal SPR. For example, the first interface 900 may be an audio interface (Integrated Interchip Sound, I2S) or a Universal Serial Bus (USB) interface. The microprocessor 10 may be a microcontroller unit (MCU) or a single-chip microcomputer. The receiving signal Rx may be any type of audio signal, and the memory access signal SPR may be a Peripheral Direct Memory Access (PDMA) signal, but the present disclosure is not limited thereto.

In one embodiment, the microprocessor 10 is configured to receive the memory access signal SPR. A buffer 310 is disposed inside the microprocessor 10, and the buffer 310 is configured to output an input pointer signal SIP and an output pointer signal SOP based on the memory access signal SPR, the input pointer signal SIP, and the output pointer signal SOP.

For example, the buffer 310 may be an actual hardware component, such as a 96-word ring buffer. The buffer 310 may also be a random-access memory (RAM), but the present disclosure is not limited thereto. In some embodiments, the buffer 310 outputs (or simultaneously outputs) the input pointer signal SIP and the output pointer signal SOP based on the input pointer signal SIP of the memory access signal SPR and the output pointer signal SOP of the memory access signal SPR, but the present disclosure is not limited thereto.

In this embodiment, the frequency adjustment circuit 20 outputs a first current threshold (such as the current threshold SCT) based on the input pointer signal SIP and the output pointer signal SOP. The frequency adjustment circuit 20 outputs a threshold trimming signal STT to the time register 110 based on the setting threshold signal SST and the first current threshold.

For example, the time register 110 may be a high-speed internal RC oscillator (HIRC). The time register 110 may output a clock signal SC to the second interface 910 based on the threshold trimming signal STT. The second interface 910 may be an audio interface (I2S) or a Discontinuous Pulse-Width Modulation (DPWM) interface. The setting threshold of the setting threshold signal SST may be a value between 1 and 96, such as 1, 48, or 96, but the present disclosure is not limited thereto.

In one embodiment, the frequency adjustment circuit 20 determines whether to output an interval trimming signal SIT based on the setting threshold of the setting threshold signal SST and the first current threshold. When the frequency adjustment circuit 20 determines that the setting threshold and the first current threshold are not equal, the frequency adjustment circuit 20 outputs the interval trimming signal SIT to the time register 110 based on the setting interval signal SSI.

For example, the setting interval value of the setting interval signal SSI may be a value between 1 and 100 milliseconds (ms), such as 1, 50, or 100, but the present disclosure is not limited thereto. In some embodiments, the frequency adjustment circuit 20 may continuously determine whether to output the interval trimming signal SIT based on the setting threshold of the setting threshold signal SST and the first current threshold.

In one embodiment, the memory access signal SPR includes an input Peripheral Direct Memory Access (PDMA) signal. The input pointer signal SIP and the output pointer signal SOP are each associated with the memory access signal.

For example, the memory access signal SPR may be an input Peripheral Direct Memory Access (PDMA) signal. The input PDMA signal is not directly input to the processor (not shown in the figure) and may be directly input to the microprocessor 10, but the present disclosure is not limited thereto.

In some embodiments, the frequency adjustment circuit 20 may output a memory access signal SPT to the second interface 910, and the second interface 910 may output a transmission signal Tx, but the present disclosure is not limited thereto. In some embodiments, the frequency adjustment circuit 20 outputs the memory access signal SPT and converts it into the transmission signal Tx, but the present disclosure is not limited thereto.

For example, the frequency adjustment circuit 20 may output an output Peripheral Direct Memory Access (PDMA) signal to the second interface 910, but the present disclosure is not limited thereto. In some embodiments, the clock (or timing) of the input PDMA signal and the output PDMA signal may be different, but the present disclosure is not limited thereto. In some embodiments, the clock (or timing) of the input PDMA signal and the output PDMA signal may be the same, but the present disclosure is not limited thereto.

In some embodiments, the clock (or timing) of the input signal Rx and the output signal Tx may be different, but the present disclosure is not limited thereto. In some embodiments, the clock (or timing) of the input signal Rx and the output signal Tx may be the same, but the present disclosure is not limited thereto.

In some embodiments, the register may output the setting threshold signal SST and/or the setting interval signal SSI, but the present disclosure is not limited thereto. In some embodiments, the processor may output the setting threshold signal SST and/or the setting interval signal SSI, but the present disclosure is not limited thereto. In some embodiments, a memory may output the setting threshold signal SST and/or the setting interval signal SSI, but the present disclosure is not limited thereto.

For example, processor may be a Central Processing Unit (CPU), a Graphics Processing Unit (GPU), a server, or the like. The processor and the microprocessor 10 may be different from each other. The memory may be a random-access memory (RAM), a read-only memory (ROM), a cache, a flash memory, a memory card, a hard drive (e.g., cloud, network, or external hard drive), an optical disc, a USB drive, a database, or the like, but the present disclosure is not limited thereto.

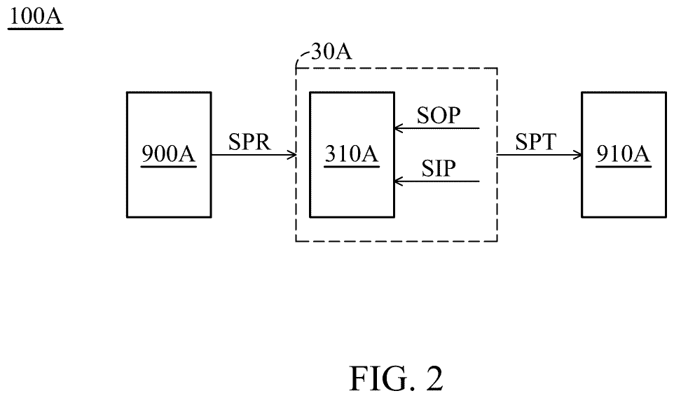

FIG. 2 is a block diagram of a frequency adjustment device according to one embodiment of the present disclosure. As shown in FIG. 2, in some embodiments, the frequency adjustment device 100A may be implemented through a software process. Specifically, the frequency adjustment device 100A includes a first interface 900A, a signal receiving block 30A, and a second interface 910A. The signal receiving block 30A includes a buffer 310A.

In this embodiment, the first interface 900A outputs the memory access signal SPR to the signal receiving block 30A. The signal receiving block 30A receives the memory access signal SPR, the input pointer signal SIP, and the output pointer signal SOP, and outputs the memory access signal SPT. The second interface 910A receives the memory access signal SPT.

For example, the signal receiving block 30A and/or the buffer 310A may achieve the effect of executing a virtual buffer through software, an application, or a programming language, but the present disclosure is not limited thereto.

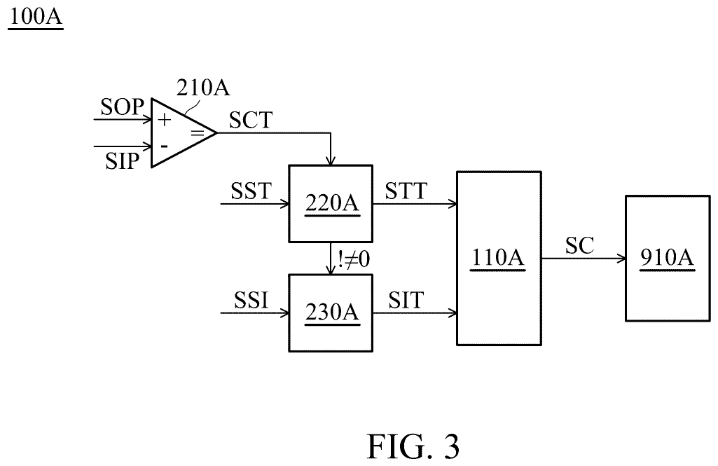

FIG. 3 is a block diagram of a frequency adjustment device according to one embodiment of the present disclosure. As shown in FIG. 3, in some embodiments, referring to FIG. 2, the frequency adjustment device 100A further includes a first selector 210A, a second selector 220A, a third selector 230A, a time register 110A, and a second interface 910A.

In this embodiment, the first selector 210A may output a current threshold signal SCT to the second selector 220A based on the input pointer signal SIP and the output pointer signal SOP. The second selector 220A may output a threshold trimming signal STT to the time register 110A based on the current threshold signal SCT and the setting threshold signal SST. The time register 110A may output a clock signal SC to the second interface 910A based on the threshold trimming signal STT.

In some embodiments, the third selector 230A may output an interval trimming signal SIT to the time register 110A based on the result determined by the second selector 220A and the setting interval signal SSI. The time register 110A may output a clock signal SC to the second interface 910A based on the threshold trimming signal STT and/or the interval trimming signal SIT.

Please refer to FIG. 2, and FIG. 3, in some embodiments, compared to FIG. 1, the frequency adjustment device 100 shown in FIG. 1 may implement all signal transmission or selection determinations entirely in hardware. The frequency adjustment device 100A may be divided into a first execution block (as shown in FIG. 2) and a second execution block (as shown in FIG. 3). Some components in the first execution block (such as the signal receiving block 30A and/or the buffer 310A) may be implemented via software (or all components), while some components (or all components) in the second execution block may be implemented in hardware, but the present disclosure is not limited thereto.

In one embodiment, the frequency adjustment device 100 includes the first interface 900, the microprocessor 10, the frequency adjustment circuit 20, the signal receiving block 30, the buffer 310, the first selector 210, the second selector 220, the third selector 230, the time register 110, and the second interface 910. The frequency adjustment circuit 20, the signal receiving block 30, the buffer 310, the first selector 210, the second selector 220, the third selector 230, the time register 110, and the second interface 910 may be located within the microprocessor 10.

In some embodiments, the first interface 900 outputs a receiving signal Rx, and the microprocessor 10 converts the receiving signal into the memory access signal SPR.

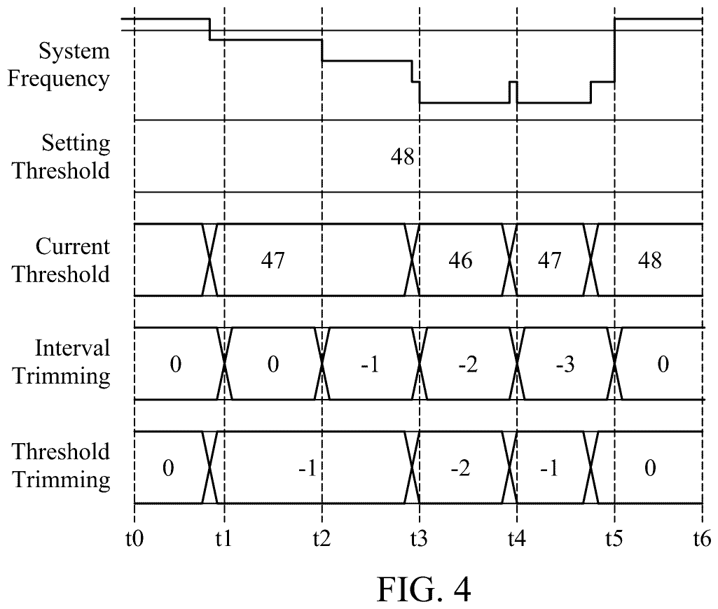

FIG. 4 is a timing diagram of a plurality of signals of a frequency adjustment device according to one embodiment of the present disclosure. As shown in FIG. 4, in some embodiments, the system frequency signal, the setting threshold signal, the current threshold signal, the interval trimming signal, and the threshold trimming signal may each correspond to different or the same values over a plurality of periods t1 to t5.

Please refer to FIG. 1 to FIG. 4, in one embodiment, during the first period from t1 to t2, the first subtractor 210 of the frequency adjustment circuit 20 sets the first difference value of the input pointer signal SIP and the output pointer signal SOP as the first current threshold.

For example, the first difference value of the input pointer signal SIP and the output pointer signal SOP may be 47, and the first current threshold may be 47, but the present disclosure is not limited thereto. Specifically, in the intelligent frequency adjustment scheme of the present disclosure, the frequency adjustment device 100 (also referred to as the frequency adjustment system) may first monitor the difference between the PDMA input pointer and the PDMA output pointer. This difference may reflect the current amount of data accumulated in the data buffer (such as the buffer 310) and is used to calculate the current threshold. The current threshold is a key parameter for determining whether it is necessary to adjust the clock frequency (such as the system frequency) to maintain stable data flow.

In this embodiment, during the first period from t1 to t2, the second subtractor 220 of the frequency adjustment circuit 20 sets the second difference value between the setting threshold and the first current threshold as the threshold trimming value of the threshold trimming signal STT.

For example, the setting threshold may be 48, the second difference value may be −1, and the threshold trimming value may be −1, but the present disclosure is not limited thereto.

In this embodiment, during the second period from t2 to t3, the second subtractor 220 of the frequency adjustment circuit 20 compares whether the setting threshold and the first current threshold are the same.

For example, in each period (not limited to the second period from t2 to t3), the second subtractor 220 may continuously compare whether the setting threshold and the current threshold obtained during that period are the same. When the setting threshold and the current threshold are not the same, the frequency adjustment circuit 20 may trigger the use of the threshold trimming value and/or the interval trimming value, but the present disclosure is not limited thereto.

In this embodiment, during the third period from t3 to t4, the frequency adjustment circuit 20 adjusts the system frequency based on the threshold trimming value and obtains a second current threshold.

For example, during the third period from t3 to t4, the frequency adjustment circuit 20 may increase or decrease the system clock frequency (such as the clock frequency of the processor) based on the threshold trimming value. Furthermore, as the system clock frequency changes, the first current threshold synchronously changes to the second current threshold, and the second current threshold may be 46, but the present disclosure is not limited thereto. In some embodiments, when the system frequency increases, the second current threshold increases relative to the first current threshold, but the present disclosure is not limited thereto. In some embodiments, when the system frequency decreases, the second current threshold decreases relative to the first current threshold, but the present disclosure is not limited thereto.

In this embodiment, during the fourth period from t5 to t6, when the second subtractor 220 of the frequency adjustment circuit 20 determines that the setting threshold and the second current threshold are the same, the second subtractor 220 of the frequency adjustment circuit 20 resets the threshold trimming value to 0. For example, the setting threshold and the second current threshold may both be 48, but the present disclosure is not limited thereto.

In some embodiments, the first period may occur after the second period, the second period may occur after the third period, and the third period may occur after the fourth period, but the present disclosure is not limited thereto. In some embodiments, each of the first period, the second period, the third period, and the fourth period may have the same duration (such as 5 ms), but the present disclosure is not limited thereto. In some embodiments, the first subtractor 210 and the second subtractor 220 may be different from each other, but the present disclosure is not limited thereto. In some embodiments, the first subtractor 210 may be the same as (or similar to) the second subtractor 220, but the present disclosure is not limited thereto.

In one embodiment, During the first period from t1 to t2, the second subtractor 220 of the frequency adjustment circuit 20 determines whether the setting threshold and the first current threshold are the same. For example, during the first period from t1 to t2, the second subtractor 220 may simultaneously determine whether the setting threshold and the first current threshold are the same and output the result to the comparator 230 described below, but the present disclosure is not limited thereto.

In this embodiment, during the second period from t2 to t3, when the second subtractor 220 of the frequency adjustment circuit 20 determines that the setting threshold and the first current threshold are not the same, the comparator 230 of the frequency adjustment circuit 20 increases or decreases the first interval trimming value of the interval trimming signal SIT by 1 to obtain the second interval trimming value.

For example, the first interval trimming value may be 0 or −1, and the second interval trimming value may be −1 or −2, but the present disclosure is not limited thereto. Furthermore, when the setting threshold is not equal to the current threshold, it may indicate that the consumption rate of the data buffer (such as the buffer 310) needs to be adjusted to achieve balance. Within each defined interval (such as each of the plurality of periods from t0 to t6), if the current threshold does not match the setting threshold, the trimming value (such as the first interval trimming value) is increased or decreased by 1 each time (in some cases, the first adjustment may be excluded). By gradually adjusting the trimming value in this manner, the system frequency (or the clock frequency) can be finely tuned, avoiding over-adjustment that could lead to instability.

In this embodiment, during the third period from t3 to t4, the frequency adjustment circuit 20 adjusts the system frequency based on the second interval trimming value and obtains the second current threshold.

For example, the second interval trimming value may be −1 or −2, and the second current threshold may be 46, 47, or 48, but the present disclosure is not limited thereto.

In this embodiment, during the fourth period from t5 to t6, when the second subtractor 220 of the frequency adjustment circuit 20 determines that the setting threshold and the second current threshold are the same, the comparator 230 of the frequency adjustment circuit 20 resets the third interval trimming value of the interval trimming signal SIT to 0.

For example, the setting threshold and the second current threshold may both be 48, and the comparator 230 may adjust the interval trimming value from −3 to 0 (such as the third interval trimming value), but the present disclosure is not limited thereto. In some embodiments, during a fifth period (occurring after the fourth period), the third interval trimming value may be 0, but the present disclosure is not limited thereto.

In some embodiments, when the interval trimming value is increased or decreased by 1, the clock frequency (or system frequency) may be increased or decreased by 500 hertz (Hz), but the present disclosure is not limited thereto. When the threshold trimming value is increased or decreased by 1, the clock frequency (or system frequency) may also be increased or decreased by 500 hertz (Hz), but the present disclosure is not limited thereto.

In some embodiments, the frequency adjustment circuit 20 sets the first difference value of the input pointer signal SIP and the output pointer signal SOP as the first current threshold. The frequency adjustment circuit 20 sets the second difference value between the setting threshold and the first current threshold as the threshold trimming value of the threshold trimming signal STT. The frequency adjustment circuit 20 compares whether the setting threshold and the first current threshold are the same. The frequency adjustment circuit 20 adjusts the system frequency based on the threshold trimming value and obtains the second current threshold. When the frequency adjustment circuit 20 determines that the setting threshold and the second current threshold are the same, the frequency adjustment circuit 20 adjusts the threshold trimming value.

In some embodiments, the frequency adjustment circuit 20 determines whether the setting threshold and the first current threshold are the same. When the frequency adjustment circuit 20 determines that the setting threshold and the current threshold are not the same, the frequency adjustment circuit 20 adjusts the first interval trimming value of the interval trimming signal SIT to the second interval trimming value. The frequency adjustment circuit 20 adjusts the system frequency based on the second interval trimming value and obtains the second current threshold. When the frequency adjustment circuit 20 determines that the setting threshold and the second current threshold are the same, the frequency adjustment circuit 20 adjusts the interval trimming signal SIT.

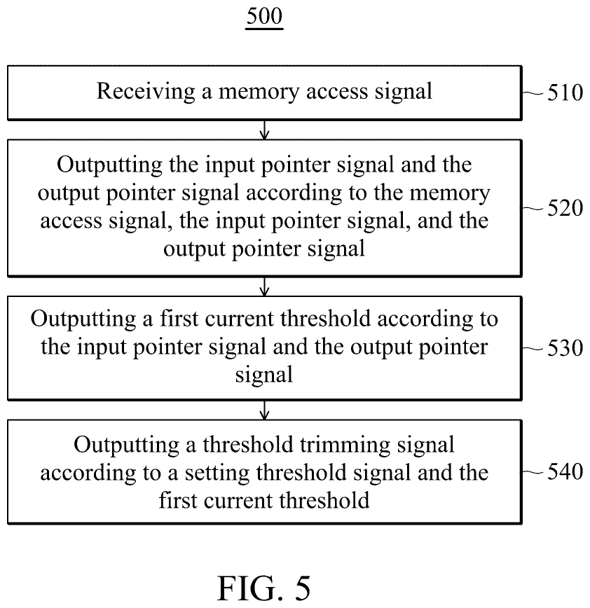

FIG. 5 is a flowchart of a plurality of signals of a frequency adjustment method according to one embodiment of the present disclosure. As shown in FIG. 5, in one embodiment, the frequency adjustment method 500 includes a plurality of steps 510 to 540, and the plurality of steps 510 to 540 will be described in detail below.

In the step 510, receiving a memory access signal.

Please refer to FIG. 1 to FIG. 5, in some embodiments, the microprocessor 10 may receive the memory access signal SPR, but the present disclosure is not limited thereto.

In the step 520, outputting the input pointer signal and the output pointer signal according to the memory access signal, the input pointer signal, and the output pointer signal.

Please refer to FIG. 1 to FIG. 5, in some embodiments, the buffer 310 may output the input pointer signal SIP and the output pointer signal SOP according to the memory access signal SPR, the input pointer signal SIP, and the output pointer signal SOP, but the present disclosure is not limited thereto.

In the step 530, outputting a first current threshold according to the input pointer signal and the output pointer signal.

Please refer to FIG. 1 to FIG. 5, in some embodiments, the frequency adjustment circuit 20 may output the first current threshold (such as the current threshold SCT) according to the input pointer signal SIP and the output pointer signal SOP, but the present disclosure is not limited thereto.

In the step 540, outputting a threshold trimming signal according to a setting threshold signal and the first current threshold.

Please refer to FIG. 1 to FIG. 5, in some embodiments, the frequency adjustment circuit 20 may output the threshold trimming signal STT according to the setting threshold signal SST and the first current threshold, but the present disclosure is not limited thereto.

Please refer to FIG. 1 to FIG. 5, in one embodiment, the frequency adjustment method 500 further includes the following steps: outputting an interval trimming signal SIT according to the setting threshold of the setting threshold signal SST and the first current threshold; and when it is determined that the setting threshold and the current threshold are not equal, outputting the interval trimming signal SIT according to the setting interval signal SSI.

For example, the frequency adjustment circuit 20 may determine whether to output an interval trimming signal SIT according to the setting threshold and the first current threshold. When the frequency adjustment circuit 20 determines that the setting threshold and the first current threshold are not equal, the frequency adjustment circuit 20 may output the interval trimming signal SIT to the time register 110 according to the setting interval signal SSI, but the present disclosure is not limited thereto.

In one embodiment, the memory access signal SPR includes an input peripheral direct memory access (PDMA) signal. The input pointer signal SIP and the output pointer signal SOP are each associated with the memory access signal.

In one embodiment, the frequency adjustment method 500 further comprises the following steps: in a first period t1 to t2, setting a first difference value between the input pointer signal SIP and the output pointer signal SOP as a first current threshold; in the first period t1 to t2, setting a second difference value between a setting threshold and the first current threshold as a threshold trimming value of the threshold trimming signal STT; in a second period t2 to t3, comparing whether the setting threshold is equal to the first current threshold; in a third period t3 to t4, adjusting a system frequency according to the threshold trimming value and obtaining a second current threshold; and in a fourth period t5 to t6, when it is determined that the setting threshold is equal to the second current threshold, resetting the threshold trimming value to 0.

For example, during the first period from t1 to t2, the first subtractor 210 of the frequency adjustment circuit 20 may set the first difference value of the input pointer signal SIP and the output pointer signal SOP as the first current threshold. During the first period from t1 to t2, the second subtractor 220 of the frequency adjustment circuit 20 may set the second difference value between the setting threshold and the first current threshold as the threshold trimming value of the threshold trimming signal STT.

Then, during the second period from t2 to t3, the second subtractor 220 of the frequency adjustment circuit 20 may compare whether the setting threshold and the first current threshold are the same. During the third period from t3 to t4, the frequency adjustment circuit 20 may adjust the system frequency based on the threshold trimming value and obtain a second current threshold. During the fourth period from t5 to t6, when the second subtractor 220 of the frequency adjustment circuit 20 determines that the setting threshold and the second current threshold are the same, the second subtractor 220 of the frequency adjustment circuit 20 may reset the threshold trimming value to 0.

In one embodiment, the frequency adjustment method 500 further includes: in a first period t1 to t2, determining whether the setting threshold and the first current threshold are the same; in a second period t2 to t3, when it is determined that the setting threshold and the current threshold are not the same, increasing or decreasing the first interval trimming value of the interval trimming signal SIT by 1 to obtain a second interval trimming value; in a third period t3 to t4, adjusting the system frequency based on the second interval trimming value and obtaining a second current threshold; and in a fourth period t5 to t6, when it is determined that the setting threshold and the second current threshold are the same, resetting the third interval trimming value of the interval trimming signal SIT to 0.

For example, during the first period from t1 to t2, the second subtractor 220 of the frequency adjustment circuit 20 determines whether the setting threshold and the first current threshold are the same. During the second period from t2 to t3, when the second subtractor 220 of the frequency adjustment circuit 20 determines that the setting threshold and the first current threshold are not the same, the comparator 230 of the frequency adjustment circuit 20 increases or decreases the first interval trimming value of the interval trimming signal SIT by 1 to obtain the second interval trimming value.

Then, during the third period from t3 to t4, the frequency adjustment circuit 20 adjusts the system frequency based on the second interval trimming value and obtains a second current threshold. During the fourth period from t5 to t6, when the second subtractor 220 of the frequency adjustment circuit 20 determines that the setting threshold and the second current threshold are the same, the comparator 230 of the frequency adjustment circuit 20 resets the third interval trimming value of the interval trimming signal SIT to 0.

In some embodiments, the frequency adjustment method 500 may be implemented in any type of programming language code, algorithm, software, or firmware, but the present disclosure is not limited thereto.

In some embodiments, frequency adjustment method 500 may be implemented by the frequency adjustment device 100, but the present disclosure is not limited thereto. In some embodiments, the frequency adjustment method 500 may be implemented via a non-transitory computer-readable storage medium, but the present disclosure is not limited thereto. In some embodiments, the frequency adjustment method 500 may be implemented by other systems or servers, but the present disclosure is not limited thereto.

In some embodiments, the frequency adjustment method 500 may allow a system (such as the frequency adjustment device 100 or a frequency adjustment system) to adjust the clock frequency more precisely based on the actual data buffer consumption. If the current threshold is greater than the setting threshold, it indicates that the data production rate is faster than the consumption rate, requiring an increase in the clock frequency; conversely, if the current threshold is lower, a decrease in the clock frequency is required, but the present disclosure is not limited thereto.

In some embodiments, the frequency adjustment method 500, through the combined use of interval trimming and threshold trimming, may flexibly and precisely adjust the clock frequency to accommodate variations in data buffer consumption, thereby ensuring the stability of the data flow and improving the overall performance and reliability of the system. The intelligent frequency adjustment scheme of the present disclosure (such as the frequency adjustment method 500) is particularly suitable for applications that require handling high-speed data streams, such as audio and video processing systems, and may effectively reduce the need for manual frequency adjustments, thereby simplifying the software development process, but the present disclosure is not limited thereto.

Therefore, according to the technical content of the present disclosure, the frequency adjustment device and frequency adjustment shown in the embodiment of the present disclosure can achieve the effect of intelligently adjusting the clock frequency by monitoring the difference between the current threshold and the setting threshold.

Furthermore, the frequency adjustment device and frequency adjustment shown in the embodiment may constitute an intelligent frequency adjustment scheme based on peripheral direct memory access (PDMA), designed to achieve a stable data buffer consumption rate, while simplifying program development and allowing the MCU to devote more resources to critical tasks.

It should also be understood that ordinal terms used in the specification and the claims, such as “first,” “second,” and the like, are used to modify elements and are not intended to imply or represent that the element(s) have any previous ordinal designation. Nor do such terms indicate any order of the elements relative to one another or in a manufacturing process. The use of these ordinal terms is merely to distinguish one element having a certain name from another element having the same name. The terms used in the claims and the specification need not be the same; for example, a “first element” in the specification may be referred to as a “second element” in the claims.

Although the specific embodiments of the present disclosure have been described above, they are not intended to limit the present disclosure. Those skilled in the art may make various modifications and alterations without departing from the principles and spirit of the present disclosure. Therefore, the scope of the present disclosure should be defined by the appended claims.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A frequency adjustment device, comprising:
a microprocessor, configured to receive a memory access signal;
a buffer, disposed inside the microprocessor, wherein the buffer is configured to output an input pointer signal and an output pointer signal according to the memory access signal, the input pointer signal, and the output pointer signal; and
a frequency adjustment circuit, disposed inside the microprocessor, wherein the frequency adjustment circuit is configured to output a first current threshold according to the input pointer signal and the output pointer signal;
wherein the frequency adjustment circuit is further configured to output a threshold trimming signal to a time register according to a setting threshold signal and the first current threshold.

2. The frequency adjustment device as claimed in claim 1, wherein
the frequency adjustment circuit determines whether to output an interval trimming signal according to a setting threshold of the setting threshold signal and the first current threshold;
wherein when the frequency adjustment circuit determines that the setting threshold is not equal to the first current threshold, the frequency adjustment circuit outputs the interval trimming signal to the time register according to a setting interval signal.

3. The frequency adjustment device as claimed in claim 1, wherein
the memory access signal comprises an input peripheral direct memory access signal;
wherein the input pointer signal and the output pointer signal are respectively associated with the memory access signal.

4. The frequency adjustment device as claimed in claim 2, wherein
the frequency adjustment circuit sets a first difference value between the input pointer signal and the output pointer signal as the first current threshold;
wherein the frequency adjustment circuit sets a second difference value between the setting threshold and the first current threshold as a threshold trimming value of the threshold trimming signal;
wherein the frequency adjustment circuit determines whether the setting threshold is equal to the first current threshold;
wherein the frequency adjustment circuit adjusts a system frequency and obtains a second current threshold according to the threshold trimming value;
wherein when the frequency adjustment circuit determines that the setting threshold is equal to the second current threshold, the frequency adjustment circuit adjusts the threshold trimming value.

5. The frequency adjustment device as claimed in claim 4, wherein
the frequency adjustment circuit determines whether the setting threshold is equal to the first current threshold;
wherein when the frequency adjustment circuit determines that the setting threshold is not equal to the first current threshold, the frequency adjustment circuit adjusts a first interval trimming value of the interval trimming signal to a second interval trimming value;
wherein the frequency adjustment circuit adjusts the system frequency and obtains the second current threshold according to the second interval trimming value;
wherein when the frequency adjustment circuit determines that the setting threshold is equal to the second current threshold, the frequency adjustment circuit adjusts the interval trimming signal.

6. A frequency adjustment method, comprising:
receiving a memory access signal;
outputting an input pointer signal and an output pointer signal according to the memory access signal, the input pointer signal, and the output pointer signal;
outputting a first current threshold according to the input pointer signal and the output pointer signal; and
outputting a threshold trimming signal according to a setting threshold signal and the first current threshold.

7. The frequency adjustment method as claimed in claim 6, further comprising:
determining whether to output an interval trimming signal according to a setting threshold of the setting threshold signal and the first current threshold; and
when it is determined that the setting threshold and the first current threshold are not equal, outputting the interval trimming signal according to a setting interval signal.

8. The frequency adjustment method as claimed in claim 6, wherein
the memory access signal comprises an input peripheral direct memory access signal;
wherein the input pointer signal and the output pointer signal are respectively associated with the memory access signal.

9. The frequency adjustment method as claimed in claim 7, further comprising:
during a first period, setting a first difference value between the input pointer signal and the output pointer signal as the first current threshold;
during the first period, setting a second difference value between the setting threshold and the first current threshold as a threshold trimming value of the threshold trimming signal;
during a second period, comparing whether the setting threshold is equal to the first current threshold;
during a third period, adjusting a system frequency according to the threshold trimming value and obtaining a second current threshold; and
during a fourth period, when it is determined that the setting threshold is equal to the second current threshold, restoring the threshold trimming value to zero.

10. The frequency adjustment method as claimed in claim 9, further comprising:
during the first period, determining whether the setting threshold is equal to the first current threshold;
during the second period, when it is determined that the setting threshold is not equal to the first current threshold, increasing or decreasing a first interval trimming value of the interval trimming signal by one to obtain a second interval trimming value;
during the third period, adjusting the system frequency according to the second interval trimming value and obtaining a second current threshold; and
during the fourth period, when it is determined that the setting threshold is equal to the second current threshold, restoring a third interval trimming value of the interval trimming signal to zero.
